(19) United States
(12) Patent Application Publication
(10) Pub. No.: US 2020/0219772 A1
(43) Pub. Date: Jul. 9, 2020

(54) MASKLESS PROCESS FOR FABRICATING GATE STRUCTURES AND SCHOTTKY DIODES

(71) Applicant: INTEL CORPORATION, Santa Clara, CA (US)

(72) Inventors: RAHUL RAMASWAMY, Portland, OR (US); NIDHI NIDHI, Hillsboro, OR (US); WALID M. HAFEZ, Portland, OR (US); JOHANN C. RODE, Hillsboro, OR (US); PAUL FISCHER, Portland, OR (US); HAN WUI THEN, Portland, OR (US); MARKO RADOSAVLJEVIC, Portland, OR (US); SANSAPTAK DASGUPTA, Hillsboro, OR (US)

(73) Assignee: INTEL CORPORATION, Santa Clara, CA (US)

(21) Appl. No.: 16/239,059

(22) Filed: Jan. 3, 2019

(51) Int. Cl. H01L 21/8252; H01L 27/06; H01L 29/20; H01L 29/205; H01L 29/778; H01L 29/872; H01L 29/66

(52) U.S. Cl. CPC H01L 21/8252; H01L 27/0605; H01L 27/0629; H01L 29/2003; H01L 29/66212; H01L 29/7787; H01L 29/872; H01L 29/66462; H01L 29/205

(57) ABSTRACT

An integrated circuit structure and methodologies of forming same. In an embodiment, the integrated circuit structure includes a transistor gate structure in a first region of semiconductor material and a diode in a second region of the semiconductor material. The gate structure has a gate electrode of conductive material with a liner along sides and a bottom of the gate electrode. The gate electrode has a gate length less than a threshold dimension value. The diode includes a body of the conductive material in contact with the semiconductor material and includes the liner along sides of the body of conductive material. The body of conductive material has a lateral dimension greater than the threshold dimension value. The liner can include, for example, a gate dielectric and a diffusion barrier in some embodiments. In other embodiments, the liner is the gate dielectric (without any diffusion barrier).

### BACKGROUND

Semiconductor devices are electronic components that exploit the electronic properties of semiconductor materials, such as silicon (Si), germanium (Ge), gallium arsenide (GaAs), and indium phosphide (InP). A field-effect transistor (FET) is a semiconductor device that includes three terminals: a gate, a source, and a drain. A FET uses an electric field applied by the gate to control the electrical conductivity of a channel through which charge carriers (e.g., electrons or holes) flow between the source and drain. In instances where the charge carriers are electrons, the FET is referred to as an n-channel device, and in instances where the charge carriers are holes, the FET is referred to as a p-channel device. Some FETs have a fourth terminal called the body or substrate, which can be used to bias the transistor. In addition, metal-oxide-semiconductor FETs (MOSFETs) include a gate dielectric between the gate and the channel. MOSFETs may also be known as metal-insulator-semiconductor FETs (MISFETSs) or insulated-gate FETs (IGFETs). Complementary MOS (CMOS) structures use a combination of p-channel MOSFET (PMOS) and n-channel MOSFET (NMOS) devices to implement logic gates and other digital circuits. A thin-film transistor (TFT) is one type of FET that can be fabricated on a substrate, for example, by depositing and patterning thin films of semiconductor material, dielectric material, and metal.

### BRIEF DESCRIPTION OF THE DRAWINGS

FIG. 1 illustrates a cross-sectional view of a transistor structure with a gate structure that includes a gate electrode and a gate dielectric, where the gate dielectric is part of a liner along the floor and sidewalls of a trench in isolation material on top of the semiconductor material, in accordance with an embodiment of the present disclosure.

FIG. 2 illustrates a cross-sectional view of a diode structure defining a metal-semiconductor interface and including a liner material along sidewalls of the conductive material, in accordance with an embodiment of the present disclosure.

FIG. 3 illustrates a cross-sectional view of part of an integrated circuit that includes a gate structure and a diode structure on common layers of semiconductor material and each having a trench lined to a different extent, in accordance with an embodiment of the present disclosure.

FIG. 4 illustrates a cross-sectional view of part of an integrated circuit that includes a gate structure and a diode structure on different layers of semiconductor material and each having a trench lined to a different extent, in accordance with an embodiment of the present disclosure.

FIG. 5 illustrates a cross-sectional view of part of an integrated circuit that includes gate and diode structures of various dimensions, where each structure includes a trench lined to an extent depending on the dimension of the trench, in accordance with an embodiment of the present disclosure.

FIGS. 6A-6D illustrate cross-sectional views of example device structures that implement gate structures fabricated in accordance with some embodiments of the present disclosure.

FIG. 7 illustrates a process flow diagram for a method of forming a transistor gate structure, in accordance with an embodiment of the present disclosure.

FIGS. 8A-8G illustrate cross-sectional views of an example integrated circuit at various stages of processing in the method of FIG. 7, in accordance with some embodiments of the present disclosure.

FIG. 9 illustrates an example computing system with an integrated circuit implementing device structures disclosed herein, in accordance with an embodiment of the present disclosure.

These and other features of the present embodiments will be understood better by reading the following detailed description, taken together with the figures herein described. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles, and some features may have surface topography or otherwise be non-smooth, given real-world limitations of fabrication processes. In short, the figures are provided merely to show example structures.

### DETAILED DESCRIPTION

Techniques are disclosed for fabricating Schottky diodes and HEMT gate structures on an integrated circuit die. In accordance with an embodiment of the present disclosure, both Schottky diodes and gate structures for HEMT devices can be fabricated in a trench defined in a layer of interlayer dielectric (ILD) on the top surface of a semiconductor material, for example. The HEMT gate structure includes a gate dielectric between the gate electrode and the semiconductor, but the diode does not and has a metal-semiconductor interface. Unlike some processes in which the diode recesses are masked while processing the HEMT gate structures and vice versa, methodologies according to an embodiment of the present disclosure utilize a maskless process that enables processing both structures at the same time. In one such embodiment, the size (e.g., width or gate length) of the trench in the ILD determines whether liner material is removed along the floor of the trench during dry etch processing. In one such example, the liner includes a high-k dielectric (e.g., hafnium oxide) in addition to a diffusion barrier (e.g., silicon nitride). In one some such example, an anisotropic dry etch process is not effective to remove the liner material along the floor of trenches having a lateral width less than about 90 nm. In contrast, the same etch removes the liner material from the floor of trenches of greater width. Thus, the trench dimension can be used to differentiate between formation of HEMT gate structures (e.g., metal-oxide-semiconductor) and Schottky diodes (e.g., metal-semiconductor) when using a process that includes deposition of the liner material in both types of trenches.

Methodologies disclosed herein can be utilized regardless of the semiconductor material(s). However, the methodologies are particularly well-suited for use with semiconductor materials used in HEMT devices, including Group III-V and Group IV semiconductors, such as silicon, indium phosphide, gallium nitride/aluminum gallium nitride, gallium arsenide/aluminum gallium arsenide, and silicon carbide, to name a few examples. In some example embodiments, the processing techniques provided herein can be used to make transistor gate structures, diodes, or Schottky-based HEMT devices, for instance. Some such devices may be positioned adjacent one another on a die or may occupy spaced-apart regions of a die. Numerous variations and embodiments will be apparent in light of the present disclosure.

General Overview

Transistors can be made using a variety of active materials, including Group III-V semiconductors. The High Electron Mobility Transistor (HEMT) is a form of field effect transistor (FET) that is used to provide very high levels of performance at microwave frequencies. Rather than a doped region as used in MOSFETs, the channel of a HEMT has a P-N heterojunction with materials of different bandgaps on opposite sides of the junction. The HEMT is often made with wide bandgap semiconductor materials, such as gallium nitride (GaN), gallium arsenide (GaAs), and silicon carbide (SiC). Electrons in the n-type region form a conductive layer below the heterojunction that is one layer thick, known as two-dimensional electron gas (2DEG). Similarly, p-type material can have a conductive layer known as 2-dimensional hole gas (2DHG). The two-dimensional electron gas (or 2DHG) resides in a channel region of an undoped semiconductor material and exhibits very high electron mobility. A bias can be applied to the gate to change the number of electrons in the channel of 2DEG (or number of holes in the 2DHG), and therefore to control the conductivity of the device. The HEMT offers desirable features that include low noise, high power, and high-frequency operation. Accordingly, the device is used in radio-frequency (RF) applications where high performance is required, such as millimeter wave communications. In some cases, the gate structure includes a gate electrode (e.g., metal) and a gate dielectric (e.g., an oxide), where the gate dielectric is between the gate electrode the active layer of semiconductor material to provide a metal-oxide-semiconductor interface. The gate dielectric may include additional materials, such as a diffusion barrier, native oxide, or other dielectric material layer.

A Schottky diode has a junction between a semiconductor and a metal. Schottky diodes have a low turn-on voltage that allows higher switching speeds and improved system efficiency. Some such diode structures can be used in the gate of a HEMT device where the gate structure has the gate electrode in contact with a semiconductor material.

As will be appreciated in light of this disclosure, the processes used to make a HEMT gate or a Schottky diode may be similar, and therefore there are synergies that can be advantageously exploited. Unfortunately, current techniques for forming HEMT devices and Schottky diodes fail to exploit such synergies. For example, fabricating each structure may begin with forming recess or via in a layer of interlayer dielectric (ILD), such as silicon dioxide, spin-on glass, or the like. The recess defines an opening to a layer of semiconductor material below the ILD. To form a Schottky diode, metal is deposited in the recess in contact with semiconductor material, resulting in a metal-semiconductor junction, or Schottky diode. To form a HEMT gate, which includes an oxide layer (for gate dielectric), the recess is lined with an oxide and, optionally, a diffusion barrier material, such as silicon nitride (Si₃N₄). The diffusion barrier material behaves like and is generally considered to be part of the gate oxide, as will be further appreciated. After lining the recess, a metal is deposited in the lined recess to define a metal-oxide-semiconductor junction. Currently, when these structures (HEMT device and Schottky diode) are fabricated on the same die, photoresist or other mask material is used to mask off some recesses or regions of the die to differentiate processing for the HEMT gate (which includes an oxide layer) and the diode (which does not have an oxide layer). For example, diode regions or recesses are masked when processing the gate structure for HEMT devices. Metal is then deposited in the lined recess, where the liner and oxide are between the metal and the semiconductor material to define a HEMT gate structure with a metal-oxide-semiconductor sequence. In separate processing with the HEMT structure masked, unlined recesses are filled with metal to define Schottky diodes. So, separate processing phases are used.

In contrast, and in accordance with an embodiment of the present disclosure, Schottky diodes and HEMT gate structures can be processed concurrently on the same die without the need for masking and separate processing phases. Instead of masking, the dimension of the recess or corresponding gate length can be used to control the etch processing, and in turn, control whether the gate dielectric (e.g., oxide) and liner are removed along the bottom surface of the recess. For example, lined recesses of less than 90 nm wide will become HEMT gate structures and lined recesses greater than 90 nm wide will become diodes. During processing, both recesses are lined with a liner (e.g., Si₃N₄) and a gate oxide along the sidewall and floor. According to some such embodiments, a dry etch is used to remove the oxide and liner along the floor of the diode recesses. However, due to the smaller dimension of the HEMT gate structure, the etch saturates and does not successfully remove the liner and oxide on the floor of the trench. Thus, the etch process results in the liner and oxide being removed along the floor in larger recesses, but not removed from the floor of smaller recesses, according to an example embodiment.

Note that the expression “active material” or “active materials” as used herein simply refers to materials as variously noted herein, and is not intended to imply that the material is currently electrically biased or otherwise in a conductive state where carriers are mobile within the material, as will plainly be apparent and appreciated. For instance, a given active material need not be connected (whether directly or indirectly) to any power source whatsoever to be considered an active material. Nor does the active material need to be in a conducting state to be considered an active material.

Likewise, the use herein of expressions such as “channel region” or “channel portion” or “source region” or “source portion” or “drain region” or “drain portion” simply refers to specific locations of a transistor structure, and is not intended to imply that the transistor itself is currently electrically biased or otherwise in a conductive state where carriers are mobile within the channel region, as will be plainly apparent and appreciated. For instance, a given transistor need not be connected (whether directly or indirectly) to any power source whatsoever to have a channel region.

Also note that the use of “source/drain” herein is simply intended to refer to a source region or a drain region or both a source region and a drain region. To this end, the forward slash (“/”) as used herein means “and/or” unless otherwise specified, and is not intended to implicate any particular structural limitation or arrangement with respect to source and drain regions, or any other materials or features that are listed herein in conjunction with a forward slash.

Further, materials that are “compositionally different” or “compositionally distinct” as used herein refers to two materials that have different chemical compositions. This compositional difference may be, for instance, by virtue of an element that is in one material but not the other (e.g., SiGe is compositionally different from silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

As also used herein, the term “low-κ” refers to a material having a dielectric constant equal to or less than that of silicon dioxide (SiO₂), which has a value of 3.9 according to some measurement methods. Examples of low-κ materials include amorphous carbon, aluminum oxide (Al₂O₃), spin-on glass, silicon oxycarbides (SiOCH), fluorine-doped SiO₂, carbon-doped SiO₂, and silsesquioxanes, to provide a few examples. As also used herein, the term “high-κ” refers to materials having a dielectric constant greater than that of silicon dioxide (SiO₂). Examples of high-κ dielectric materials include hafnium dioxide (HfO₂), zirconium dioxide (ZrO₂) and titanium dioxide (TiO₂) to provide some examples.

As also used herein, the expression “X includes at least one of A or B” refers to an X that may include, for example, just A only, just B only, or both A and B. To this end, an X that includes at least one of A or B is not to be understood as an X that requires each of A and B, unless expressly stated. For instance, the expression “X includes A and B” refers to an X that expressly includes both A and B. Moreover, this is true for any number of items greater than two, where “at least one” item is included in X. For example, as used herein, the expression “X includes at least one of A, B, or C” refers to an X that may include just A only, just B only, just C only, only A and B (and not C), only A and C (and not B), only B and C (and not A), or each of A, B, and C. This is true even if any of A, B, or C happens to include multiple types or variations. To this end, an X that includes at least one of A, B, or C is not to be understood as an X that requires each of A, B, and C, unless expressly stated. For instance, the expression “X includes A, B, and C” refers to an X that expressly includes each of A, B, and C. Likewise, the expression “X included in at least one of A or B” refers to an X that may be included, for example, in just A only, in just B only, or in both A and B. The above discussion with respect to “X includes at least one of A or B” equally applies here, as will be appreciated.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. In particular, in some embodiments, TEM can be useful to show a cross section of an integrated circuit or die that includes multiple HEMT gate structures, where the height of the gate dielectric along the sidewall of the gate electrode varies according to the gate length or lateral dimension of the lined trench. Similarly, TEM can be used to show a Schottky diode having sidewalls lined with dielectric and/or barrier material, which is indicative of depositing a liner in diode recesses and in gate recesses. Additionally, TEM can be used to show Schottky diodes and HEMT devices on the same die, where the diodes have lined sidewalls and a lateral dimension above a threshold dimension value (e.g., 90 nm), and where the HEMT gate structures have lined sidewalls and floor as well as a lateral dimension below the threshold dimension value.

Architecture

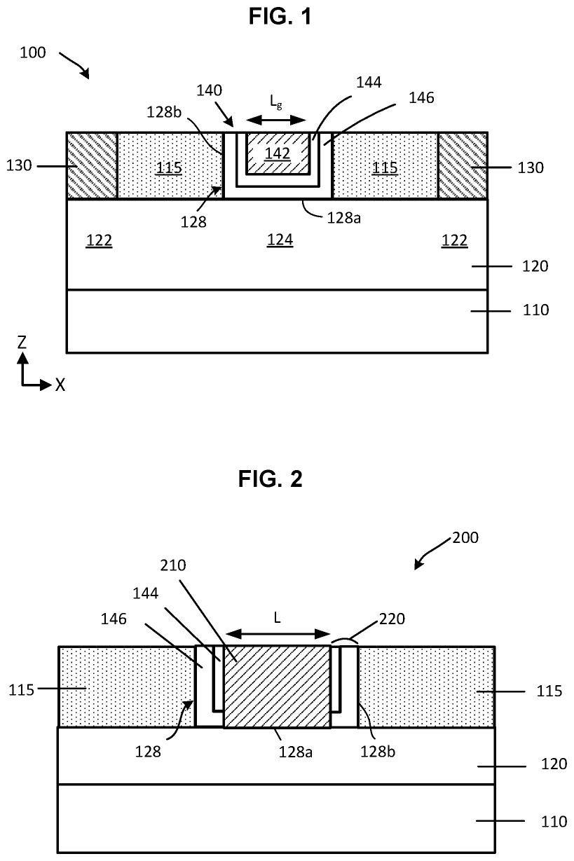

FIG. 1 illustrates a cross-sectional (X-Z) view of a transistor structure 100 that includes a layer of semiconductor material 120 on a substrate 110. A layer of interlayer dielectric (ILD) 115 is on the top surface of the semiconductor material 120. ILD 115 may also be referred to as an insulator, passivation material, isolation material, low-k dielectric, or spacer, as will be appreciated. Source and/or drain (S/D) 130 contact the top surface of the semiconductor material 120 at respective source/drain regions 122. A gate structure 140 is located between the S/D 130 and makes contact with the semiconductor material 120 above a corresponding channel region 124. The gate structure 140 includes a gate electrode 142 and gate dielectric 144, where the gate dielectric 144 is between the gate electrode 142 and the semiconductor material 120.

As shown in this example embodiment, ILD 115 fills the regions between the gate structure 140 and the S/D 130. Note the ILD 115, like other depicted features, is not necessarily drawn to scale (e.g., it may be narrower in other embodiments). This structure can be achieved by depositing the materials of the gate structure 140 and S/D 130 in recesses or trenches 128 in the ILD 115, as will be discussed in more detail below. In this example, the gate dielectric 144 contacts the sidewalls and bottom of the gate electrode 142. A liner or diffusion barrier 146 is on the substantially vertical)(±5° walls 128b and horizontal floor 128a of the trench 128 of the gate structure 140. For example, the diffusion barrier 146 is on the outside of the gate dielectric 144, including between the gate dielectric 144 and ILD 115 and between the gate dielectric and the semiconductor material 120.

In one example, the lateral dimension of the gate electrode 142, also referred to as the gate length L_{g}, has a predefined value of about 90 nm or less. In other embodiments, the gate length L_{g} is 70 nm or less, 50 nm or less, 30 nm or less, or other dimension suitable for the device size.

In one embodiment, the diffusion barrier 146 is silicon nitride (e.g., Si₃N₄). The thickness of the diffusion barrier 146 is about 5 nm. The gate dielectric 142 has a thickness of about 5 nm to 15 nm, including about 8-10 nm. Together, the thickness of the diffusion barrier 146 and gate dielectric 142 is about 10-20 nm (e.g., 15 nm) along the sidewalls and along the bottom of the gate electrode 142, in accordance with some embodiments. Other thicknesses can be achieved depending on deposition techniques and parameter values, as will be appreciated.

Although illustrated as a single layer, the semiconductor material 120 may include more than one compositionally distinct semiconductor material in some embodiments. For example, the semiconductor material 120 includes two semiconductors that define a p-n heterojunction. In one such embodiment, the semiconductor material 120 includes a layer of aluminum gallium nitride (AlGaN) and a layer of gallium nitride (GaN), one or both of which may be doped. In another embodiment, the semiconductor material 120 includes a layer of gallium arsenide (GaAs) and a layer of aluminum gallium arsenide (AlGaAs). Each material may also include a doped region and an undoped region, or a graded concentration of dopant atoms. Numerous suitable materials and material combinations will be apparent in light of the present disclosure.

In some embodiments, the transistor structure 100 can be configured as a high-electron mobility transistor (HEMT), for use in high-frequency switching or power amplification, for example. In other embodiments, the transistor structure 100 is part of a memory structure, such as a block of DDR SDRAM.

Referring now to FIG. 2, a cross-sectional view illustrates a diode structure 200 in accordance with an embodiment of the present disclosure. The diode structure 200 includes a layer of semiconductor material 120 on a substrate 110. A layer of ILD 115 is on the top of the semiconductor material 120. A trench 128 (or “diode trench”) extends through the ILD 115 to the semiconductor material 120. A metal 210 in the trench 128 extends to and contacts the semiconductor material 120, forming a metal-semiconductor junction or Schottky diode. As shown in this example, a liner 220 is on sidewalls 128b of the trench 128 between the metal 210 and the ILD 115. The liner 220 can include one or more materials. In one embodiment, the liner 220 includes the gate dielectric 144 and the diffusion barrier 146 of a gate structure 140 on the same die (e.g., transistor structure 100 discussed above). In some embodiments, the gate dielectric 144 has a reduced lateral thickness on the vertical sidewalls compared to that of the transistor structure 100 on the die, as may result from etch processing to remove the liner 220 along the floor 128a of the trench 128. In yet other embodiments, the gate dielectric 144 may be removed completely from the diode trench 128.

The diode metal 210 has a lateral dimension L. In some embodiments, the lateral dimension L is 90 nm or greater, such as 100 nm, 110 nm, 120 nm, 150 nm, 200 nm, 250 nm, or more. Such values of lateral dimension L enable dry etch processes to remove the liner 220 along the bottom or floor 128a of the trench 228, thereby opening the trench 228 along the floor 128a to expose the semiconductor material 120. As a result, depositing the metal 210 in the trench 128 in contact with the semiconductor material 120 results in a Schottky diode. The diode structure 200 may be part of a protective circuit in an integrated circuit, or may be a Schottky gate for a transistor, for example.

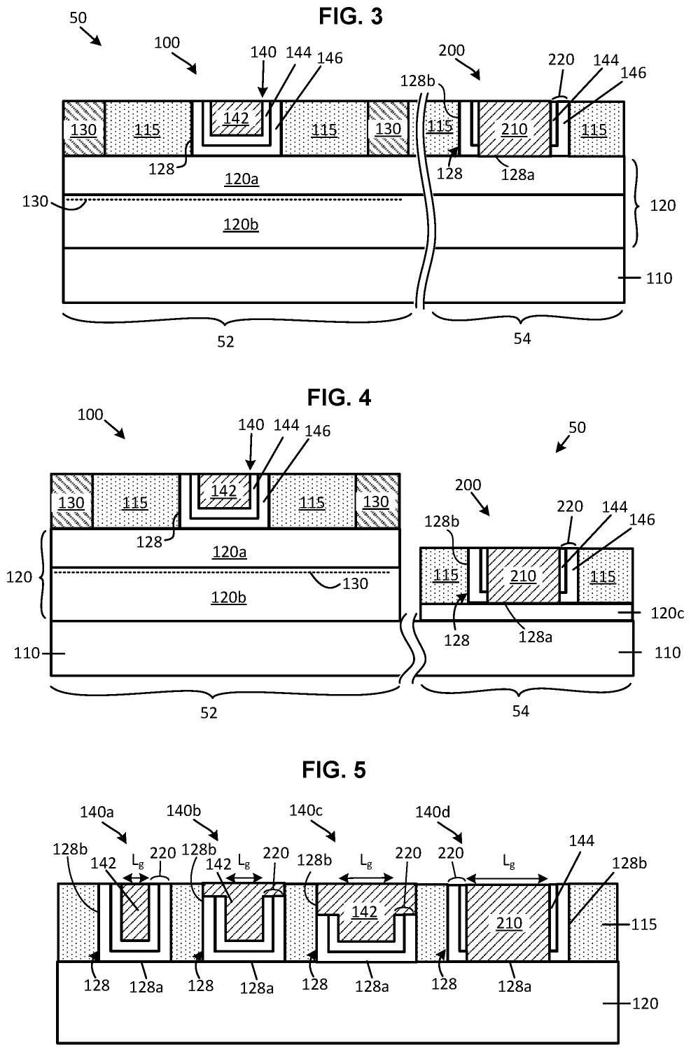

Referring now to FIGS. 3-4, cross-sectional views illustrate a portion of an integrated circuit or die 50 that includes a transistor structure 100 in a first region 52 and a diode structure 200 in a second region 54. The first region 52 may be immediately adjacent the second region 54, or may be spaced from the second region 54. The example embodiment of FIG. 3 shows the transistor structure 100 and the diode structure 200 formed on a common semiconductor material 120 with the gate electrode 142 and metal 210 of the diode 200 in a common plane, but this is not required. It is contemplated that the transistor structure 100 and the diode structure 200 may have different vertical positions in the integrated circuit and, accordingly, may involve different semiconductor materials 120. As shown in FIG. 4, for example, the diode structure 200 can be formed on a base layer of semiconductor material 120c on the substrate 110 while the gate structure 140 of the transistor structure 100 can be formed on semiconductor material 120a (e.g., a mesa) that is on or above the layer of semiconductor material 120c used for the diode. The examples structures of FIGS. 3 and 4 are discussed concurrently below.

The die 50 includes a layer of semiconductor material 120 on a substrate 110. In some embodiments, the semiconductor material 120 includes a first semiconductor material 120a and a second semiconductor material 120b that are compositionally distinct. In some such embodiments, the first and second semiconductor materials 120a, 120b have different bandgaps and define a heterojunction. For example, the semiconductor material 120 includes AlGaN/GaN heterojunction or an AlGaAs/GaAs heterojunction. In other embodiments, the heterojunction is defined between a single layer of semiconductor material 120 and the substrate 110, which itself may be a semiconductor, such as silicon or silicon carbide. In some embodiments, the semiconductor material 120 includes an undoped semiconductor with a two-dimensional electron gas (2DEG) 132 or two-dimensional hole gas (2DHG). The semiconductor material 120 can include more layers, including layers of undoped or doped semiconductor material and/or lattice buffer layers, as will be appreciated. Numerous suitable materials and material combinations are available.

The transistor structure 100 is configured as a planar HEMT with S/D 130 on a top surface of the semiconductor material 120. The gate structure 140 is between the S/D contacts 130 and makes contact with the top surface of the semiconductor material 120. In other embodiments, the S/D 130 or the gate structure 140 can be recessed with respect to one another. In yet other embodiments, the S/D 130 make contact with a side of the semiconductor material 120. As illustrated in the example embodiment depicted, the S/D 130 and gate structure 140 are recessed into, or surrounded by, a layer of passivation material or ILD 115. The gate structure 140 includes a gate electrode 142 surrounded on its sidewalls and bottom by a gate dielectric 144, such as a high-k oxide. An optional barrier material 146 surrounds the gate dielectric 144 on its sidewalls and bottom, thereby lining the vertical sidewalls and floor of the trench 128. Note that the barrier material 146 is considered to be part of the oxide based on its function and behavior, as will be appreciated. The gate structure 140 defines a metal-oxide-semiconductor interface as consistent with HEMT architecture.

The diode structure 200 includes a metal 210 in direct contact with the semiconductor material 120 (e.g., semiconductor material 120a or 120c). The metal-semiconductor interface defines a Schottky diode that may be used as a gate structure, as a diode used to protect the integrated circuit, or for some other purpose, as will be appreciated. A liner 220 is present on the sidewalls 128b between the metal 210 and the ILD 115, but not on the floor 128a of the recess 128 between the metal 210 and the semiconductor material 120. The liner 220 includes the barrier 146 material and the gate dielectric 144 as found in the gate structure 140, in some embodiments. The lateral thickness of the gate dielectric 144 may be reduced along sidewalls of the metal 210 compared to the lateral thickness of the gate dielectric 144 along sidewalls of the gate electrode 142. Such geometry may result from etch processing, examples of which are discussed in more detail below.

Referring now to FIG. 5, a cross-sectional view illustrates an example integrated circuit with gate structures 140 that were processed at the same time and have a variety of gate lengths L_{g}. Gate lengths L_{g} have values from about 30 nm (far left of FIG. 5) to about 110 nm (far right of FIG. 5). Depending on etch methodologies and etch parameters of a given process, a value of gate length L_{g} can be used for selective removal of the liner along the floor 128a of the trench 128. Therefore, gate length L_{g} can determine whether a HEMT gate structure or Schottky diode results from maskless processing. For example, the recess 128 is defined through the ILD 115 to expose the semiconductor material 120. The liner 220, including the diffusion barrier 146 and high-k dielectric 144, is deposited conformally in the recess 128. A masking material, such as photoresist or carbon hardmask is then deposited in the lined recesses 128. For lined recesses 128 above a predefined value of gate length L_{g}, initial wet etch processing completely removes the masking material. For lined recesses 128 below a predefined value of gate length L_{g}, initial wet etch processing only partially removes the masking material, if at all. Subsequent dry etch processing can then be used to remove the exposed liner 220 along the floor 128a of recess 128 with a gate length L_{g} above the predefined value. In trenches 128 where the masking material is not completely removed, the dry etch is blocked from acting on the liner along the floor 128a. After the dry etch, an additional wet etch can be used to remove any remaining masking material, resulting in some trenches 128 having a liner on the entire trench floor 128a and others without a liner on the floor 128a (e.g., the liner is removed from the floor between liner sidewalls). The metal 210 of the diode structure 200 or gate electrode 142 of the gate structure 140 can then be deposited in the recess 128. A method of fabrication is discussed in more detail below.

At the far left of FIG. 5, gate structure 140a has a gate length of about 30 nm. Wet etch processing failed to remove masking material (e.g., photoresist or carbon hard mask) in the lined trench 128. Subsequent dry etch processing minimally etched the liner 220 on sidewalls 128b of the trench 128. After further wet etching to remove the masking material, conductive material of the gate electrode 142 was deposited in the lined trench 128.

Moving slightly to the right in FIG. 5, gate structure 140b has a gate length of about 60 nm. Here, due to the increased gate length, the wet etch process partially removed the masking material, resulting in the exposed liner 220 being recessed along the sidewalls 128b during subsequent dry etch processing. As a result, the liner 220 is reduced in height, but remains intact along the floor 128a of the trench 128 due to being protected by the masking material from dry etch processing. After subsequent wet etch processing to remove the masking material, conductive material was deposited over the lined trench 128 and recessed liner sidewalls to result in a gate electrode 142 with a T-shape.

Gate structure 140c has a gate length L_{g} of about 90 nm. Here, despite further increased gate length L_{g}, wet etch processing still was unable to fully remove the masking material in the lined trench 128. To the extent that the masking material was removed, subsequent dry etch processing recessed the exposed liner 220 along the sidewalls 128b, but left intact the liner 220 along the floor 128a of the trench 128. After subsequent wet etch processing to remove the masking material, the gate electrode 142 was deposited over the partially lined trench 128 to result in a gate electrode 142 that again has a T-shape.

At the far-right side of FIG. 5, the gate structure 140d has a gate length of 110 nm. Here, wet etch processing effectively removed the masking material from the lined trench 128. The larger gate length allowed the wet etch processing to act rapidly on the masking material, thereby removing it from the trench 128. Subsequent dry etch processing removed the liner 220 along the floor 128a and some of the liner 220 along the sidewalls 128b. Part of the gate dielectric 144 was removed along the vertical sidewall 128b, resulting in a reduced lateral thickness of the liner 220 along sidewalls 128b. The deposited metal 210 contacts the semiconductor material 120.

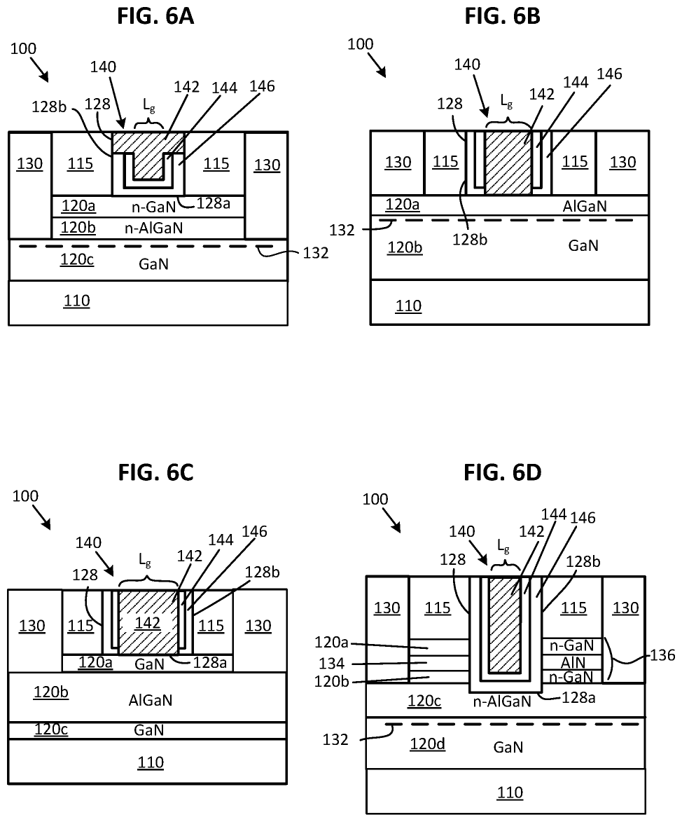

Referring now to FIGS. 6A-6D, cross-sectional views illustrate example device structures that implement gate structures 140 in accordance with the present disclosure. FIG. 6A is an example HEMT transistor structure 100. The gate structure 140 has a gate length L_{g} of about 50 nm and includes a gate electrode 142 and gate dielectric 144 where the gate dielectric 144 is between the gate electrode 142 and semiconductor material 120a (e.g., n-GaN). The gate electrode 142 resides in a trench 128 in ILD 115 that is lined along the floor 128a and part of the sidewalls 128b with the gate dielectric 144 and a diffusion barrier material 146. Layers of semiconductor material 120a (e.g., n-GaN), 120b (e.g., n-AlGaN), and 120c (e.g., undoped GaN) are on a substrate 110 of silicon or silicon carbide. The semiconductor material 120c (undoped GaN) defines a heterojunction with semiconductor material 120b (n-AlGaN) and includes a conductive channel of two-dimensional electron gas 132. The bottom of the source and drain 130 are recessed with respect to that of the gate structure 140. The S/D 130 make contact with the top of the semiconductor material 120c of undoped GaN while the gate structure 140 is on the semiconductor material 120a of n-type GaN.

FIG. 6B is an example HEMT transistor structure 100 with a Schottky diode gate structure 140 having a gate length L_{g} of about 100 nm. The gate structure 140 includes a gate electrode 142 in contact with semiconductor material 120a (e.g., AlGaN). The gate electrode 142 resides in a trench 128 in ILD 115 that is lined along the sidewalls 128b with the gate dielectric 144 and a diffusion barrier material 146. Layers of semiconductor material 120a (e.g., AlGaN) and 120b (e.g., undoped GaN) are on a substrate 110 of silicon or silicon carbide. Semiconductor layer 120b is an active layer or carrier layer that defines a heterojunction with semiconductor material 120a (AlGaN). Semiconductor layer 120b has a channel of two-dimensional electron gas 120. The S/D 130 and gate structure 140 have a planar configuration and make contact with the top of the AlGaN semiconductor material 120a.

FIG. 6C is an example of a HEMT transistor structure 100 with a Schottky diode gate structure 140 with a gate length L_{g} of about 130 nm. The gate structure 140 includes a gate electrode 142 in contact with semiconductor material 120a (e.g., GaN). The gate electrode 142 resides in a trench 128 in ILD 115 that is lined along the sidewalls 128b with the gate dielectric 144 and a diffusion barrier material 146. Layers of semiconductor material 120a (GaN), 120b (AlGaN), and 120c (GaN) are on a substrate 110 of silicon or silicon carbide, for example. The source and drain 130 are recessed with respect to the gate structure 140. The source and drain 130 make contact with semiconductor material 120b (AlGaN) and the diode gate structure 140 contacts the top of the upper layer of semiconductor material 120a (GaN).

FIG. 6D is another example of a HEMT transistor structure 100 as may be useful in a power supply for electronics. The gate structure 140 has a gate length L_{g} of about 30 nm and includes a gate electrode 142 and gate dielectric 144 where the gate dielectric 144 is between the gate electrode 142 and semiconductor material 120c (e.g., n-type AlGaN). The gate electrode 142 resides in a trench 128 that extends to semiconductor material 120c through ILD 115 cap structure 136. For example, the cap structure 136 is a three-layer structure that includes a layer of isolation material 134 (e.g., aluminum nitride) between layers of semiconductor material 120a, 120b (e.g., n-type GaN). The trench 128 is lined along the floor 128a and sidewalls 128b with the gate dielectric 144 and a diffusion barrier material 146. Semiconductor material 120c (e.g., n-AlGaN) is on semiconductor material 120d (e.g., undoped GaN), which is on a substrate 110 of silicon or silicon carbide. Semiconductor layer 120d (GaN) can be referred to as a carrier layer or channel layer with two-dimensional electron gas 132 for carrier electrons. The source and drain 130 and gate structure 140 have a generally planar configuration and make contact with a top of semiconductor material 120c (n-AlGaN).

Fabrication Methodologies

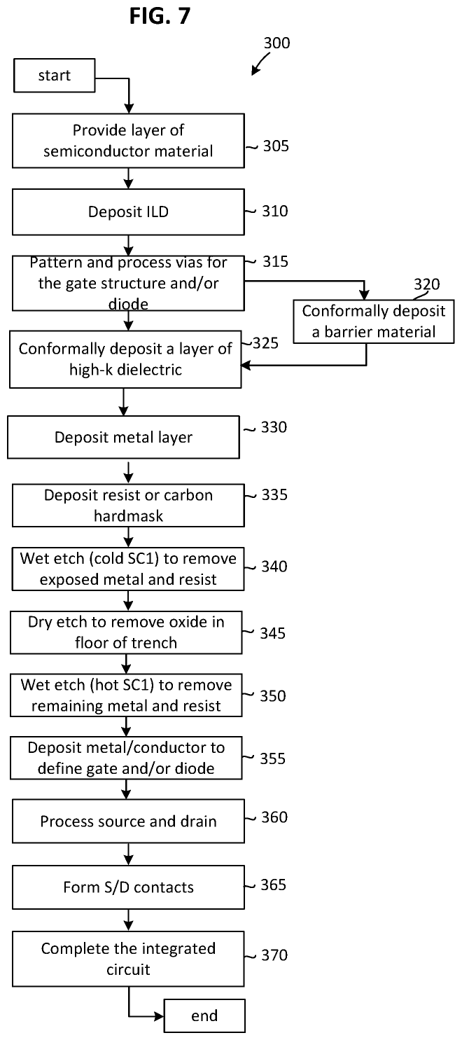

Referring now to FIG. 7, a flow chart illustrates a process flow in a method 300 of fabricating an integrated circuit, in accordance with some embodiments. Method 300 is discussed in the context of an integrated circuit that includes both a planar HEMT device and a diode structure 200. However, method 300 can be performed with modifications as needed to fabricate other devices and geometries. In general, method 300 can be performed using any suitable semiconductor fabrication techniques, including deposition, photolithography, wet or dry chemical etching processes (e.g., plasma etch and SC1 etch), chemical mechanical polishing, deposition or epitaxial growth processes (e.g., CVD, PVD, ALD, VPE, MBE, LPE), melt regrowth, and/or any other suitable processing, as will be appreciated.

Method 300 begins with providing 305 a layer of semiconductor material 120. The semiconductor material 120 can be one of a plurality of material layers on a substrate 110. For example, the semiconductor material 120 is a Group III-V semiconductor, a group IV semiconductor, transition metal dichalcogenide (TMD), or other semiconductor material. The semiconductor material 120 can be one or more material of a stack that includes a plurality of layers, such as a substrate, a buffer layer, a bandgap or lattice transition material, a barrier layer, an active material layer, a spacer material, doped semiconductor materials, undoped or minimally doped semiconductor materials, dielectrics, oxides, and/or passivation materials, for example. The layer of semiconductor material 120 can include one or more materials with a variety of configurations, including n-type or p-type semiconductor material, doped or undoped material, and materials of different bandgaps. The layer of semiconductor material 120 may include distinctly defined regions of semiconductor material 120 spaced and isolated from one another, such as mesas arranged in an array. In some embodiments, the semiconductor material 120 defines a p-n heterojunction. For example, the semiconductor material 120 includes gallium nitride (GaN) and aluminum gallium nitride (AlGaN), or indium gallium arsenide (InGaAs) and gallium arsenide (GaAs), or silicon (Si) and silicon carbide (SiC), or other material combinations. In another example, the semiconductor material 120 is a layer of gallium nitride or other Group III-V semiconductor material 120 on an insulating substrate 110. The semiconductor material 120 may be a thin film, a blanket layer, or bulk semiconductor material in some embodiments. In one example, the semiconductor material 120 is grown on or transferred to a substrate 110. Numerous suitable variations and embodiments will be apparent in light of the present disclosure.

Examples of Group III-V materials include, but are not limited to, aluminum nitride (AlN), aluminum arsenide (AlAs), aluminum gallium arsenide (AlGaAs), gallium arsenide (GaAs), aluminum gallium nitride (AlGaN), gallium nitride (GaN), indium phosphide (InP), and indium aluminum phosphide (InAlP). Examples of Group IV materials include silicon (Si), silicon carbide (SiC), germanium (Ge), and silicon germanium (SiGe). TMDs have a general formula of MₐX_{b}, where a and b are from 0-10. The chalcogen atom X is selected from sulfur (S), selenium (Se), and tellurium (Te) and the metal atom M is selected from titanium (Ti), zirconium (Zr), silver (Ag), iron (Fe), zinc (Zn), osmium (Os), vanadium (V), manganese (Mn), gold (Au), cadmium (Cd), mercury (Hg), niobium (Nb), technetium (Tc), tantalum (Ta), hafnium (Hf), cobalt (Co), ruthenium (Ru), chromium (Cr), copper (Cu), palladium (Pd), rhodium (Rh), nickel (Ni), molybdenum (Mo), tungsten (W), iridium (Ir), rhenium (Re), and platinum (Pt). Examples of particular TMDs have a formula of MX₂ and include MoS₂, WS₂, MoSe₂, WSe₂, WTe₂, and MoTe₂.

In some embodiments, multiple different semiconductor materials 120 are found different areas of the substrate, such as for CMOS applications. For instance, a first semiconductor material 120 on a first area of the substrate 110 may be used for one or more PMOS devices and a second semiconductor material 120 on a second area of the substrate 110 to be used for one or more NMOS devices. By selecting the substrate 110 to have the desired properties (e.g., lattice constant), multiple different semiconductor materials 120 can be grown, deposited, or transferred to the substrate 110. For instance, in some such embodiments, a first region 52 of the substrate 110 includes a n-type group III-V or group IV material and a second region 53 includes a p-type group III-V or group IV material.

Method 300 continues with depositing 310 a layer of interlayer dielectric (ILD) 115 on the semiconductor material 120, followed by planarizing the structure using chemical-mechanical polishing, in accordance with an embodiment. The ILD can be an insulator, passivation material, other suitable material. In some embodiments, the ILD material can be aluminum oxide (Al₂O₃), silicon nitride (Si₃N₄), silicon dioxide (SiO₂), carbon-doped silicon dioxide (SiO₂:C), or spin-on glass, to name a few examples.

Method 300 continues with defining 315 one or more vias or trenches 128 in the ILD 115 for subsequent processing of the gate structure 140 and/or diode structure 200. Each trench 128 extends through the ILD 115 to (and optionally into) the semiconductor material 120. Lithography and etch processing may be used to define 315 the trenches 128, as will be appreciated. In one embodiment, an anisotropic etch is used to define the trenches 128 in locations corresponding to the channel region 124 of the semiconductor material 120. The size (e.g., diameter or horizontal dimension) of each trench 128 can be selected to be greater than or less than a predefined value. For example, the predefined value is a threshold dimension value that indicates whether dry etch processing will remove a liner 220 from the floor 128a of the trench 128. The predefined value may be the actual dimension of the trench 128 or may represent the gate length L_{g} or lateral dimension of the lined trench 128 opening. In some embodiments, the predefined value of the horizontal dimension or gate length L_{g} is 150 nm or less, including 130 nm or less, 120 nm or less, 110 nm or less, 100 nm or less, 90 nm or less, 80 nm or less, 70 nm or less, 60 nm or less, 50 nm or less, 40 nm or less, or 30 nm or less.

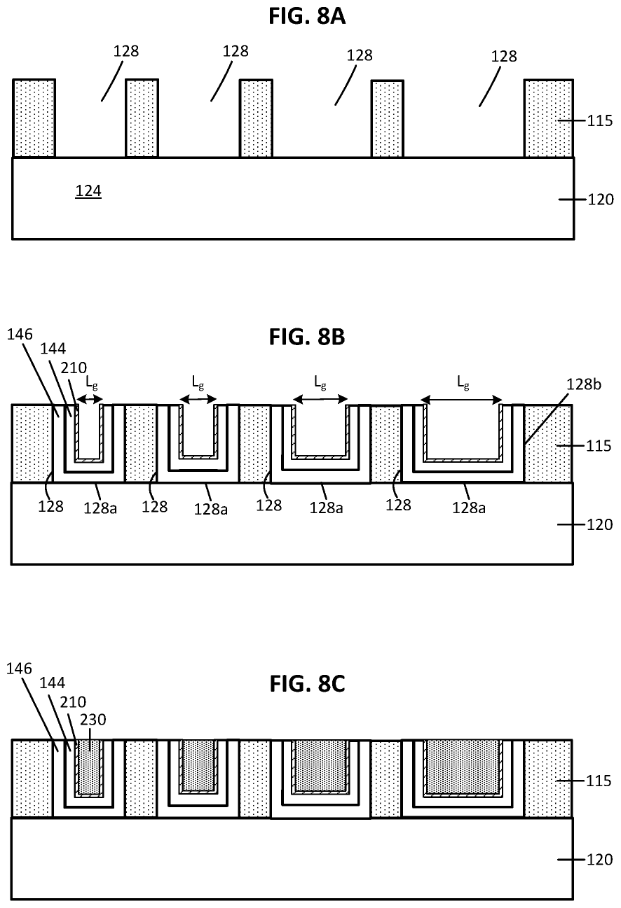

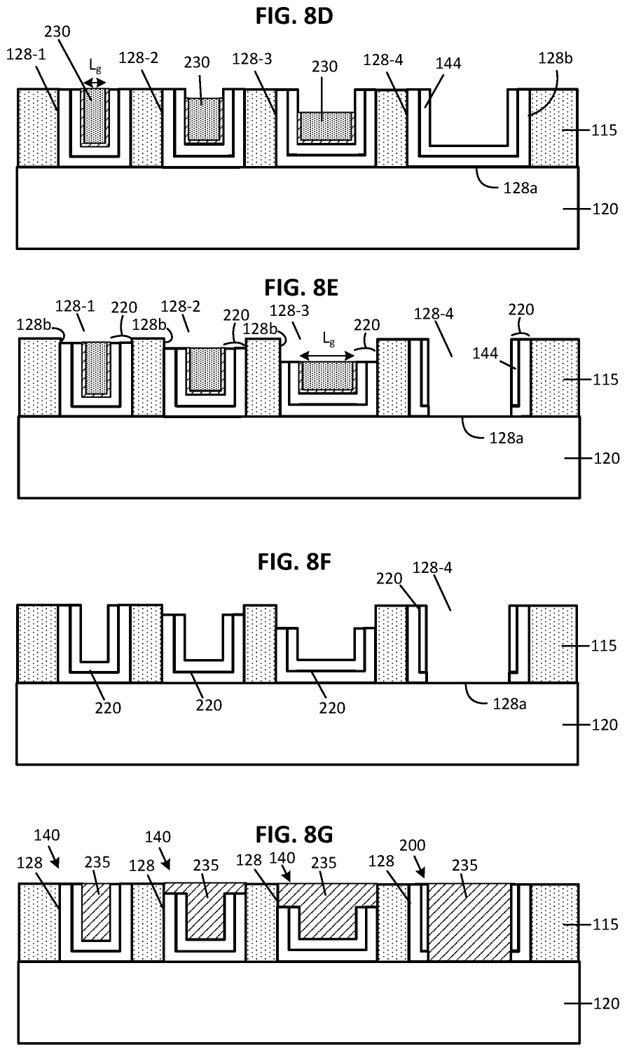

FIG. 8A illustrates a cross-sectional view of a semiconductor material 120 with ILD 115 patterned and etched to define trenches 128 that extend through the ILD to the semiconductor material 120. At the left side of FIG. 8A, the trench 128 is over a channel region 124. The trenches 128 shown in FIG. 8A increase in lateral dimension from the left-most trench 128 to the right-most trench 128. Note that the trenches 128 of FIG. 8A are illustrated as being closely spaced from one another by ILD 115 for convenience of illustration; however, such trenches 128 can be part of adjacent devices, can be part of devices spaced across regions of a circuit, or part of devices spaced across regions of a die, for example.

Method 300 optionally continues with conformally depositing 320 a layer of barrier material or diffusion barrier 146 over the etched ILD 115. For example, the diffusion barrier 146 is a metal or ceramic that coats the sidewalls and floor of each trench 128. In some embodiments, the diffusion barrier 146 is silicon nitride (e.g., Si₃N₄) or other material of sufficient conductivity to make electrical contact with the semiconductor material 120 while also limiting diffusion of certain metals or elements. Examples of suitable materials for the diffusion barrier 146 include cobalt, ruthenium, tantalum, tantalum nitride, indium oxide, tungsten nitride, and titanium nitride. In some embodiments, the diffusion barrier 146 is deposited using atomic layer deposition (ALD) to a thickness less than 10 nm, including less than 8 nm, less than 6 nm, less than 5 nm, less than 4 nm, less than 3 nm, less than 2 nm, less than 1.5 nm, and less than 1.0 nm.

Method 300 continues with conformally depositing 325 a layer of gate dielectric 144 (e.g., a high-κ dielectric). In some embodiments, the gate dielectric 144 is an oxide, such as hafnium oxide (HfO₂) or zirconium oxide (ZrO₂). Other suitable high-κ dielectric materials can be used. The gate dielectric 144 is deposited with a thickness comparable to that of the diffusion barrier 146 (when present). For example, the gate dielectric 144 has a thickness of less than 20 nm, including less than 15 nm, less than 10 nm, less than 8 nm, less than 6 nm, less than 5 nm, less than 4 nm, less than 3 nm, less than 2 nm, less than 1.5 nm, and less than 1.0 nm. In some embodiments, the gate dielectric 144 includes a plurality of compositionally distinct dielectric materials. In combination, the gate dielectric 144 and the diffusion barrier 146 have a thickness of about 15 nm, in accordance with some embodiments.

Method 300 continues with depositing 330 a metal layer 210 over the gate dielectric 144. The metal layer 210 can be deposited using ALD, for example. In some embodiments, the metal layer 210 is aluminum and has a thickness of about 5 nm. The metal layer 210 can have a thickness of 1-2 nm in some embodiments.

FIG. 8B illustrates a cross-sectional view of the structure of FIG. 8A after depositing a diffusion barrier 146, a gate dielectric 144, and a metal layer 210 along the floor 128a and sidewalls 128b of each trench 128. The resulting dimension of the lined trenches 128 defines a gate length L_{g}.

Method 300 continues with depositing 335 a masking material 230, such as photo resist or carbon hardmask in the lined trenches 128. The masking material 230 can be deposited, spun on, or applied using any suitable process. FIG. 8C illustrates the structure of FIG. 8B after depositing 335 masking material 230.

Method 300 continues with wet etching 340 to remove exposed metal layer 210. In one embodiment, wet etching 340 is a room temperature SC1 etch, which includes ammonium hydroxide, water, and hydrogen peroxide. The wet etch 340 removes the mask material 230 to varying degrees in each trench 128, depending on the dimension of the trench 128. For example, wet etching 340 completely removes the mask material 230 from lined trench 128-4 with a dimension greater than 90 nm (right side of FIG. 8D). The mask material 230 is removed to lesser degrees for lined trenches 128-1, 128-2, and 128-3 that have a gate length L_{g} or dimension less than 90 nm. For example, mask material 230 is minimally or not at all removed from lined trench 128-1 with a dimension of 30 nm and is partially removed from lined trenches 128-2 and 128-3 with dimensions of 50 nm and 70 nm, respectively. After removing the mask material 230, the wet etching 340 can act on the gate dielectric 144 (e.g., an oxide) to reduce its thickness along the sidewalls 128b of the trench 128. As a result, trench 128d for a diode structures 200 may exhibit a gate dielectric 144 along the sidewall 144b that has a reduced lateral thickness compared to that of a HEMT gate structure 140 on the same die. FIG. 8D illustrates the structure of FIG. 8C after wet etching 340 to remove or partially remove the mask material 230.

Method 300 continues with dry etching 345 the liner 220 (e.g., includes gate dielectric 144 and diffusion barrier 146) where exposed. Dry etching 345 removes the liner 220 from the floor 128a of trenches 128 greater than 90 nm or other predefined dimension. In accordance with an embodiment, the dry etching 345 is an anisotropic plasma etch that effectively removes the liner 220 from the floor of trenches 128 where the mask material 230 was removed during wet etching 340. In trenches 128 with remaining mask material 230, dry etching 345 minimally affects the liner 220 and mask material 230. That is, the mask material 230 protects the floor 128a of such trenches 128 so that dry etching 345 does not remove the liner 220 at that location.

FIG. 8E illustrates the structure of FIG. 8D after dry etching 345. Note that the liner 220 has been removed from the floor 128a of trench 128-4. Also, the liner 220 exposed along the sidewalls 128b of trenches 128-1, 128-2, and 128-3 is partially recessed by an amount corresponding to the gate length L_{g} or dimension of the lined trench 128. For example, the liner 220 in trench 128-1 is minimally recessed after dry etching 345 while the liner 220 of trench 128-3 is recessed along sidewalls 128b to a greater extent due to its greater dimension. Note also that the lateral thickness of the gate dielectric 144 in trench 128-4 has been reduced as a result of the dry etching 345.

Method 300 continues with additional dry etching 350 to remove the metal layer 210 and remaining mask material 230. In one embodiment, the additional dry etching 350 uses an SC1 etch at elevated temperature (e.g., ˜70-80° C.) to lift off the remaining metal layer 210 and mask material 230. Even when the metal layer 210 has a thickness of 1-2 nm, for example, the additional dry etching 350 can effectively remove it. FIG. 8F illustrates the structure of FIG. 8E after additional dry etching 350 using a hot SC1 etch to remove remaining metal 210 and mask material 230 from each trench 128. Lined trenches 128 below 90 nm are lined along the floor 128a and at least partially along the sidewalls 128b. The liner has been removed from the floor 128a of lined trench 128-4, which has a dimension greater than 90 nm.

Method 300 continues with depositing 355 conductive material 235 in the lined trenches 128 of gate structures 140 and/or trenches with lined sidewalls 128b of diode structures 200. The conductive material becomes the gate electrode 142 and/or diode metal. The conductive material may comprise a wide range of metals, alloys, or other conductive materials, such as polysilicon, aluminum (Al), tungsten (W), titanium (Ti), tantalum (Ta), copper (Cu), titanium nitride (TiN), or tantalum nitride (TaN), for example. In diode structures 200, the conductive material makes direct contact with the semiconductor material 120 to define a metal-semiconductor junction or Schottky diode. In HEMT gate structures 140, the conductive material is deposited over the liner 220, which may include the gate dielectric 144 and diffusion barrier 146, to define a metal-oxide-semiconductor junction. FIG. 8G illustrates the structure of FIG. 8F after depositing 355 conductive material 235 in the trenches 128 to define either a gate structure 140 or a diode structure 200.

Method 300 continues with processing 360 the source and drain 130 using any suitable techniques, in accordance with an embodiment of the present disclosure. In some embodiments, portion of the semiconductor material 120 may be recessed or removed in regions corresponding to the S/D 130, followed by growth or deposition of replacement S/D material. Replacement S/D material may be grown using any suitable techniques, such as vapor-phase epitaxy (VPE), molecular beam epitaxy (MBE), or liquid-phase epitaxy (LPE), for example. In other embodiments, the source and drain are processed by doping or cladding the semiconductor material 120. In some embodiments, the S/D 130 may be formed one polarity at a time, such as processing one of n-type and p-type S/D, and then processing the other of the n-type and p-type S/D. In some embodiments, the source and drain may include any suitable doping scheme, such as including suitable n-type and/or p-type dopant (e.g., in a concentration in the range of 1E16 to 1E22 atoms per cubic cm). However, in some embodiments, at least one source or drain may be undoped/intrinsic or relatively minimally doped, such as including a dopant concentration of less than 1E16 atoms per cubic cm, for example.

In some embodiments, one or more of the S/D 130 may have a multilayer structure including two or more distinct layers, for example. In some such embodiments, one or more of the layers of the S/D 130 may include grading (e.g., increasing and/or decreasing) the content/concentration of one or more materials in some or all of the S/D 130. For instance, in some embodiments, it may be desired to gradually increase the concentration of a given dopant or element as a given S/D 130 is formed, such as to reduce dopant diffusion. For example, the semiconductor material 120 has a relatively lower doping concentration near the channel region 124 and a relatively higher doping concentration near the corresponding S/D 130 for improved contact resistance.

In some embodiments, the source and drain 130 comprise the same compound as semiconductor material 120, except perhaps for the presence or concentration of dopants. For instance, the semiconductor material 120 and source/drain 130 are GaN, in one example embodiment. When the semiconductor material 120 and source and drain 130 are the same material (not considering dopants), the boundary between these structures can be seen using conductive AFM scan or scanning spreading resistance microscopy (SSRM), for example, to identify boundaries based on conductivity. In other embodiments, the source and drain 130 are compositionally different from semiconductor material 120 in contact with the gate structure 140. For example, when the semiconductor material 120 is GaN, the source and drain 130 can be AlGaN or GaN with different dopant concentrations, to name a few examples. In another example, the semiconductor material 120 is GaAs and the source and drain 130 can be InGaAs. Transmission electron microscopy (TEM) can be used to see the boundary between compositionally different materials in accordance with some embodiments.

Method 300 continues with forming 365 source/drain contacts sing any suitable techniques, such as depositing metal or metal alloy (or other suitable electrically conductive material) on the S/D 130. In some embodiments, forming 365 source/drain contacts may include silicidation, germanidation, III-V-idation, and/or annealing processes, for example. In some embodiments, the source and drain contacts may include aluminum or tungsten, although any suitable conductive metal or alloy can be used, such as silver, nickel-platinum, or nickel-aluminum, for example. In some embodiments, one or more of the source and drain contacts may include a resistance reducing metal and a contact plug metal, or just a contact plug, for instance. Example contact resistance reducing metals include, for instance, nickel, aluminum, titanium, gold, gold-germanium, nickel-platinum, nickel aluminum, and/or other such resistance reducing metals or alloys. Example contact plug metals include, for instance, aluminum, copper, nickel, platinum, titanium, or tungsten, or alloys thereof, although any suitably conductive contact metal or alloy may be used.

In some embodiments, additional layers may be present in the source and drain contacts, such as adhesion layers (e.g., titanium nitride) and/or liner or barrier layers (e.g., tantalum nitride), if so desired. In some embodiments, a contact resistance-reducing layer may be present between a given source or drain region and its corresponding source or drain contact, such as a relatively highly doped (e.g., with dopant concentrations greater than 1E18, 1E19, 1E20, 1E21, or 1E22 atoms per cubic cm) intervening semiconductor material layer, for example. In some such embodiments, the contact resistance-reducing layer may include semiconductor material and/or impurity dopants based on the included material and/or dopant concentration of the corresponding source or drain region, for example.

Method 300 continues by completing 370 a general integrated circuit (IC) as desired, in accordance with some embodiments. Such additional processing to complete an IC may include back-end or back-end-of-line (BEOL) processing to form one or more metallization layers and/or interconnect in contact with the transistor devices formed, for example. Any other suitable processing may be performed, as will be apparent in light of this disclosure.

Note that the processes in method 300 are shown in a particular order for ease of description. However, one or more of the processes may be performed in a different order or may not be performed at all (and thus be optional), in accordance with some embodiments. Although method 300 is discussed above as an example series of processes, it is to be understood that there is no required order to the processes unless specifically indicated. For example, S/D processing can be performed before or after gate processing. Also, processes described above are not exhaustive and some processes may include additional processing, such as lithography, deposition of isolation layers, and other such processes, as will be appreciated. Further, method 300 may include processing for dummy structures, such as a dummy gate structure, dummy S/D 130, and other intermediate processing. Method 300 has numerous variations and embodiments, as will be apparent.

### Example System

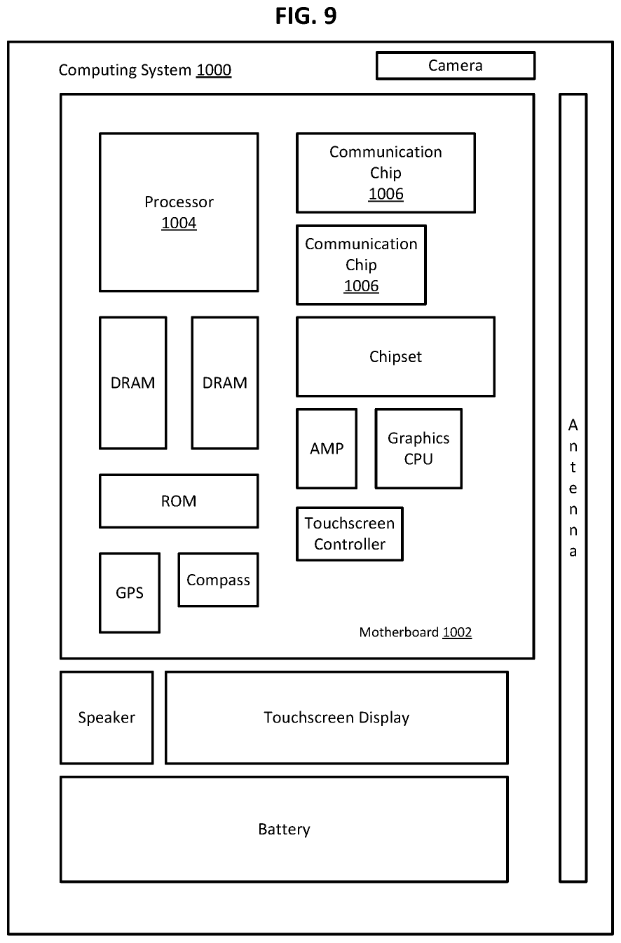

FIG. 9 illustrates a computing system 1000 implemented with the integrated circuit structures or techniques disclosed herein, according to an embodiment of the present disclosure. As can be seen, the computing system 1000 houses a motherboard 1002. The motherboard 1002 may include a number of components, including, but not limited to, a processor 1004 (including embedded memory, such as an eDRAM incorporating recessed thin-channel TFTs as described herein) and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, to name a few examples.

Depending on its applications, computing system 1000 may include one or more other components that may or may not be physically and electrically coupled to the motherboard 1002. These other components may include, but are not limited to, volatile memory (e.g., dynamic random access memory (DRAM) or embedded dynamic random access memory (eDRAM)), nonvolatile memory (e.g., read-only memory (ROM), resistive random-access memory (RRAM), and the like), a graphics processor, a digital signal processor, a crypto (or cryptographic) processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices (e.g., one or more memory cells, one or more memory cell arrays) formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, and the like that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices (e.g., one or more memory cells) formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices (e.g., one or more memory cells) formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing device 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices (e.g., one or more memory cells) formed using the disclosed techniques, as variously described herein.

### Further Example Embodiments

The following examples pertain to further embodiments, from which numerous permutations and configurations will be apparent.

Example 1 is an integrated circuit comprising a semiconductor material with a first portion and a second portion; a transistor structure on the first portion, the transistor structure including a source region, a drain region spaced from the source region, and a gate structure in contact with the first portion of the semiconductor material between the source region and the drain region, the gate structure comprising a conductive material and a dielectric material, the dielectric material extending along sidewalls and a bottom of the conductive material; and a diode structure on the second portion, the diode structure including (i) a body of the conductive material in contact with the second portion of the semiconductor material and (ii) the dielectric material, wherein the dielectric material is also extending along sidewalls of the body of the conductive material.

Example 2 includes the subject matter of Example 1, wherein the dielectric material includes a high-k dielectric.

Example 3 includes the subject matter of Example 2, wherein the high-k dielectric is an oxide.

Example 4 includes the subject matter of Example 2, wherein the high-k dielectric comprises hafnium and oxygen.

Example 5 includes the subject matter of any of Examples 2-4, wherein the dielectric material is part of a liner, and the liner further includes a diffusion barrier in addition to the high-k dielectric.

Example 6 includes the subject matter of Example 5, wherein the diffusion barrier comprises aluminum and nitrogen.

Example 7 includes the subject matter of any of Examples 1-6, wherein the gate electrode has a horizontal dimension of at least 100 nm between the source region and the drain region.

Example 8 includes the subject matter of Example 7, wherein the gate electrode comprises a metal in direct contact with the body.

Example 9 includes the subject matter of Examples 7 or 8, wherein the gate structure defines a Schottky diode.

Example 10 includes the subject matter of any of Examples 1-6, wherein a portion of the dielectric material extends between the gate electrode and the body.

Example 11 includes the subject matter of Example 10, wherein the gate electrode has a horizontal dimension of not more than 90 nm between the source region and the drain region.

Example 12 includes the subject matter of Example 11, wherein the horizontal dimension is not more than 70 nm.

Example 13 includes the subject matter of Example 11, wherein the horizontal dimension is not more than 50 nm.

Example 14 includes the subject matter of any of Examples 10-13, wherein the semiconductor material and the gate structure are part of a high-electron mobility transistor (HEMT).

Example 15 includes the subject matter of any of Examples 1-14, wherein the semiconductor material comprises a Group III-V semiconductor.

Example 16 includes the subject matter of any of Examples 1-15, wherein the Group III-V semiconductor comprises gallium and nitrogen.

Example 17 includes the subject matter of any of Examples 1-16, wherein the semiconductor material includes a two-dimensional electron gas.

Example 18 is an integrated circuit comprising a layer of semiconductor material; and a plurality of gate structures on the layer, each of first and second gate structures of the plurality including a gate electrode of conductive material and a liner along sidewalls and a bottom of the gate electrode; wherein the first gate structure includes a first gate electrode of a first gate length, and the second gate structure includes a second gate electrode of a second gate length less than the first gate length; wherein the liner includes a first liner of a first height along sidewalls of the first gate electrode and a second liner of a second height along sidewalls of the second gate electrode, the first height being less than the second height.

Example 19 includes the subject matter of Example 18, wherein the liner has a thickness from 5 to 25 nm along the sidewall and the bottom of the gate electrode.

Example 20 includes the subject matter of Examples 18 or 19, wherein the liner comprises a high-k dielectric.

Example 21 includes the subject matter of Example 20, wherein the high-k dielectric is an oxide.

Example 22 includes the subject matter of any of Examples 20-21, wherein the liner further comprises a diffusion barrier.

Example 23 includes the subject matter of Example 22, wherein the diffusion barrier comprises aluminum and nitrogen.

Example 24 includes the subject matter of any of Examples 18-23, wherein the first gate length and the second gate length are 90 nm or less.

Example 25 includes the subject matter of Example 24, wherein the second gate length is less than 50 nm.

Example 26 includes the subject matter of any of Examples 18-25 and further comprises a diode with a body of the conductive material in contact with the layer of semiconductor material, wherein the liner is also along sidewalls of the body of conductive material.

Example 27 includes the subject matter of Example 26, wherein the body of conductive material has a lateral dimension greater than 90 nm.

Example 28 includes the subject matter of any of Examples 18-27, wherein the layer of semiconductor material comprises a Group III-V semiconductor.

Example 29 includes the subject matter of Example 28, wherein the semiconductor material comprises gallium and nitrogen.

Example 30 includes the subject matter of any of Examples 18-29, wherein the layer of semiconductor material includes a first semiconductor material of a first bandgap and a second semiconductor material of a second bandgap different from the first bandgap, the second semiconductor material in contact with the first semiconductor.

Example 31 includes the subject matter of Example 30, wherein one of the first semiconductor material and the second semiconductor material includes a two-dimensional electron gas.

Example 32 is an integrated circuit die comprising semiconductor material on a substrate; a layer of isolation material on the semiconductor material; a diode on a first region, the diode including a conductive material in a diode recess defined in the isolation material, the conductive material in direct contact with the semiconductor material; and a liner on sidewalls of the diode recess between the conductive material and the isolation material; and a transistor structure on a second region, the transistor structure including a source and a drain in contact with the semiconductor material; and a gate structure in a gate recess defined in the isolation material between the source and the drain, the gate structure including a gate electrode of the conductive material and the liner along sides and a bottom of the get electrode.

Example 33 includes the subject matter of Example 32, wherein the liner comprises a high-k dielectric.

Example 34 includes the subject matter of Example 33, wherein the liner further comprises a diffusion barrier material.

Example 35 includes the subject matter of Examples 33 or 34, wherein the high-k dielectric has a first thickness between the gate electrode and sidewalls of the isolation material and wherein the high-k dielectric has a second thickness between the conductive material of the diode and sidewalls of the isolation material, the second thickness less than the first thickness.

Example 36 includes the subject matter of Example 35, wherein the first thickness is from 5 nm to 20 nm.

Example 37 includes the subject matter of any of Examples 33-36, wherein the high-k dielectric comprises oxygen.

Example 38 includes the subject matter of Example 34, wherein the diffusion barrier comprises nitrogen.

Example 39 includes the subject matter of any of Examples 32-38, wherein a thickness of the liner between a sidewall of the conductive material of the diode and the isolation material is less than a thickness of the liner between a sidewall of the gate electrode and the isolation material.

Example 40 includes the subject matter of any of Examples 32-39, wherein the conductive material of the diode has a first lateral dimension greater than a threshold dimension value and the gate electrode has a second lateral dimension less than or equal to the threshold dimension value.

Example 41 includes the subject matter of Example 40, wherein the threshold dimension value is less than 100 nm.

Example 42 includes the subject matter of Example 41, wherein the threshold dimension value is less than 70 nm.

Example 43 includes the subject matter of Example 41, wherein the threshold dimension value is less than 50 nm.

Example 44 is a method of making an integrated circuit, the method comprising providing a substrate comprising a semiconductor material and a layer of isolation material on the semiconductor material; defining a first recess in the isolation material, the first recess extending to the semiconductor material and having a first lateral dimension greater than a threshold dimension value; defining a second recess in the isolation material, the second recess extending to the semiconductor material and having a lateral dimension less than the threshold dimension value; depositing a liner conformally in the first recess and the second recess to provide a lined first recess and a lined second recess; depositing a mask material in the lined first recess and the lined second recesses; removing the mask material from the lined first recess; etching through the liner on a floor of the lined first recess to expose the semiconductor material in the lined first recess; removing remaining mask material from the first recess and the second recess; and depositing a conductive material in the first recess and the second recess, wherein the liner extends along sidewalls of the conductive material in the first recess and the liner extends along a floor and sidewalls of the conductive material in the second recess.

Example 45 includes the subject matter of Example 44, wherein the liner comprises a high-k dielectric.

Example 46 includes the subject matter of Example 45, wherein the liner further comprises a diffusion barrier.

Example 47 includes the subject matter of any of Examples 44-46, wherein the threshold dimension value is no greater than 130 nm.

Example 48 includes the subject matter of Example 47, wherein the threshold dimension value is no greater than 100 nm.

Example 49 includes the subject matter of Example 47, wherein the threshold dimension value is no greater than 70 nm.

Example 50 includes the subject matter of any of Examples 44-49, wherein removing the mask material from the first recess is performed using a wet etch at room temperature.

Example 51 includes the subject matter of any of Examples 44-50, wherein etching through the liner on the floor of the first recess is performed with a dry etch.

Example 52 includes the subject matter of Example 51, wherein the dry etch saturates for recesses with a lateral dimension less than the threshold dimension value.

Example 53 includes the subject matter of any of Examples 44-52, wherein the first recess results is part of a Schottky diode and the second recess is part of a gate structure.

Example 54 includes the subject matter of Example 53, wherein the gate structure is part of a high-electron mobility transistor.

Example 55 is a computing system comprising the integrated circuit of any of claims 1-31 or the integrated circuit die of any of claims 32-43.

Example 56 includes the subject matter of Example 55 and further comprises a touch screen display.

Example 57 includes the subject matter of Examples 55 or 56 and further comprises a processor.

Example 58 includes the subject matter of any of Examples 55-57 and further comprises a communication chip.

Example 59 includes the subject matter of any of Examples 55-58, further comprising a power supply.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit comprising:
a semiconductor material with a first portion and a second portion;
a transistor structure on the first portion, the transistor structure including
a source region,
a drain region spaced from the source region, and
a gate structure in contact with the first portion of the semiconductor material between the source region and the drain region, the gate structure comprising a conductive material and a dielectric material, the dielectric material extending along sidewalls and a bottom of the conductive material; and
a diode structure on the second portion, the diode structure including (i) a body of the conductive material in contact with the second portion of the semiconductor material and (ii) the dielectric material, wherein the dielectric material is also extending along sidewalls of the body of the conductive material.

2. The integrated circuit of claim 1, wherein the dielectric material includes a high-k dielectric.

3. The integrated circuit of claim 2, wherein the dielectric material is part of a liner, and the liner further includes a diffusion barrier in addition to the high-k dielectric.

4. The integrated circuit of claim 2, wherein a portion of the dielectric material extends between the gate electrode and the body and wherein the gate electrode has a horizontal dimension of not more than 90 nm between the source region and the drain region.

5. The integrated circuit of claim 4, wherein the horizontal dimension is not more than 70 nm.

6. The integrated circuit of claim 4, wherein the semiconductor material and the gate structure are part of a high-electron mobility transistor (HEMT).

7. The integrated circuit of claim 6, wherein the semiconductor material comprises a Group III-V semiconductor.

8. The integrated circuit of claim 7, wherein the Group III-V semiconductor comprises gallium and nitrogen.

9. The integrated circuit of claim 7, wherein the semiconductor material includes a two-dimensional electron gas

10. An integrated circuit comprising:
a layer of semiconductor material; and
a plurality of gate structures on the layer, each of first and second gate structures of the plurality including a gate electrode of conductive material and a liner along sidewalls and a bottom of the gate electrode;
wherein the first gate structure includes a first gate electrode of a first gate length, and the second gate structure includes a second gate electrode of a second gate length less than the first gate length;
wherein the liner includes a first liner of a first height along sidewalls of the first gate electrode and a second liner of a second height along sidewalls of the second gate electrode, the first height being less than the second height.

11. The integrated circuit of claim 10, wherein the liner comprises a high-k dielectric.

12. The integrated circuit of claim 11, wherein the liner further comprises a diffusion barrier.

13. The integrated circuit of claim 10, wherein the first gate length and the second gate length are 90 nm or less.

14. The integrated circuit of claim 10, further comprising:
a diode with a body of the conductive material in contact with the layer of semiconductor material, wherein the liner is also along sidewalls of the body of conductive material, wherein the body of conductive material has a lateral dimension greater than 90 nm.

15. The integrated circuit of claim 10, wherein the layer of semiconductor material comprises:
a first semiconductor material of a first bandgap; and
a second semiconductor material of a second bandgap different from the first bandgap, the second semiconductor material in contact with the first semiconductor;
wherein one of the first semiconductor material and the second semiconductor material includes a two-dimensional electron gas.

16. An integrated circuit die comprising:
semiconductor material on a substrate;
a layer of isolation material on the semiconductor material;
a diode on a first region, the diode including
a conductive material in a diode recess defined in the isolation material, the conductive material in direct contact with the semiconductor material; and
a liner on sidewalls of the diode recess between the conductive material and the isolation material; and
a transistor structure on a second region, the transistor structure including
a source and a drain in contact with the semiconductor material; and
a gate structure in a gate recess defined in the isolation material between the source and the drain, the gate structure including a gate electrode of the conductive material and the liner along sides and a bottom of the get electrode.

17. The integrated circuit die of claim 16, wherein the liner comprises a high-k dielectric and a barrier material, the high-k dielectric having a first thickness between the gate electrode and sidewalls of the isolation material and having a second thickness between the conductive material of the diode and sidewalls of the isolation material, the second thickness being less than the first thickness.

18. The integrated circuit die of claim 16, wherein a thickness of the liner between a sidewall of the conductive material of the diode and the isolation material is less than a thickness of the liner between a sidewall of the gate electrode and the isolation material.

19. The integrated circuit die of claim 16, wherein the conductive material of the diode has a first lateral dimension greater than a threshold dimension value and the gate electrode has a second lateral dimension less than or equal to the threshold dimension value.

20. The integrated circuit die of claim 19, wherein the threshold dimension value is less than 100 nm.
